(19) United States
(12) Patent Application Publication
(10) Pub. No.: US 2011/0203517 A1
(43) Pub. Date: Aug. 25, 2011

(54) DEVICE AND METHOD FOR THE PRODUCTION OF SILICON BLOCKS

(76) Inventors: Bernhard Freudenberg, Coburg (DE); Mark Hollatz, (US); Matthias Trempa, Erlangen (DE); Christian Reimann, Munchaurach (DE); Jochen Friedrich, Eckental (DE)

(21) Appl. No.: 13/030,795

(22) Filed: Feb. 18, 2011

(30) Foreign Application Priority Data
Feb. 25, 2010 (DE) 10 2010 002 360.4

(51) Int. Cl. C30B 11/02; B28B 7/38; B05D 3/06

(52) U.S. Cl. 117/81; 117/223; 427/133; 427/555

(57) ABSTRACT

A device for the production of silicon blocks comprising a vessel for receiving a silicon melt with at least one vessel wall, with the at least one vessel wall comprising a nucleation-inhibiting coating on at least part of an inside or with the at least one vessel wall consisting of a nucleation-inhibiting material.

### BACKGROUND OF THE INVENTION

1. Field of the Invention

The invention relates to a device and to a method for the production of silicon blocks and to a method for the production of such a device.

2. Background Art

The production of silicon blocks having a predetermined crystal structure is decisive for the production of semiconductor components. The usual procedure for producing such silicon blocks is to crystallize a silicon melt. Controlling the crystallisation process is however difficult and elaborate.

### SUMMARY OF THE INVENTION

It is therefore the object of the invention to improve a device and a method for the production of silicon blocks. Moreover, it is the object of the invention to provide a method for the production of such a device.

This object is achieved by the features of a device for the production of silicon blocks comprising a vessel for receiving a silicon melt, with at least one vessel wall comprising a nucleation-inhibiting surface on at least part of an inner side and with the at least one vessel wall comprising at least one, in particular several nucleation bases on its inner side which is provided with the nucleation-inhibiting surface for assisting the formation of crystallization nuclei of the silicon melt; by the features of a device in which the entirety of all nucleation bases covers a surface portion of no more than 25%, in particular no more than 10%, preferably no more than 3% of the inside of the at least one vessel wall; and by the features of a method where the nucleation-inhibiting coating is applied to the inside of the vessel in the form of a nanoparticulate colloid. The gist of the invention is to provide at least a portion of the surface of a melting pot or a coquille with a nucleation-inhibiting region which is formed by the pot material and/or by a coating on the pot material and/or by defining nucleation-inhibiting materials which are placed on the coated or uncoated pot bottom. It has been found according to the invention that different materials have different boundary surface energies relative to a silicon melt, which allows the tendency of heterogeneous nucleation to be influenced in a targeted manner.

The assessment of whether a material is nucleation-inhibiting or nucleation-enhancing, is based according to the invention on the wetting behaviour of the material or liquid silicon, in particular on the contact angle between the material and liquid silicon. In this regard, small contact angles (wetting) correspond to nucleation-enhancing properties while large contact angles (dewetting) correspond to nucleation-inhibiting properties.

A decisive factor for selecting the materials is the relative proportion of the respective contact angles to the silicon melt, with the result that the nucleation-enhancing regions have a smaller contact angle relative to the silicon melt than the nucleation-inhibiting regions. The nucleation-enhancing regions should in particular have a contact angle of <90° while the nucleation-inhibiting regions should have a contact angle of >90°.

According to the above paragraph, it is possible to compile a “ranking system” of practicable materials which are ordered with respect to their respective contact angles relative to the silicon melt at approx. Tₘ (Si), i.e. at approx. 1413° C. (see table 1).

TABLE 1
Different materials and their contact angles with
liquid silicon at T~Tₘ(Si)

| | Contact angle |
|---|---|
| Material | (indicative) |
| silicon carbides (SiC) | smaller than 70° |
| graphite with an SiC-coating | |
| silicon nitrides (Si₃N₄) | smaller than 90° |
| silicon oxides (SiO₂) | approx. than 90° |
| silicon oxynitrides (SiN₂O; | larger than 90° |
| general formula: Si—OₓN_{y}) | |
| boron nitride (BN) | larger than 110° |

The targeted application of a nucleation-inhibiting coating on the greatest portion of the inside of the vessel for receiving the silicon melt, in particular on the vessel bottom, is a simple means of influencing the crystallization process of the silicon melt in a targeted manner. As an alternative to a coating, the pot material, in particular at the pot bottom, may also be replaced by a nucleation-inhibiting material, or regions of the pot may be covered with special materials which influence nucleation. Furthermore, a combination of the mentioned possibilities is conceivable.

Suitable coatings are in particular compounds which comprise silicon and oxygen components, in particular silicon oxide or silicon oxynitride. For such compounds, supercooling temperatures in the range of 20° K. up to over 100° C. below the melting point of silicon have been determined by experiment. The probability of an unwanted, spontaneous boundary surface nucleation is therefore reduced considerably.

Furthermore, the pot material, in particular at the pot bottom, may be replaced by materials which have a nucleation-inhibiting effect, in particular silicon oxynitride or boron nitride ceramics.

A particular advantage of the above-mentioned nucleation-inhibiting materials is that their compatibility and interaction with silicon is easily controllable, in particular when using silicon oxides, silicon oxynitrides and silicon nitrides.

A targeted arrangement of nucleation bases allows the formation of a defined crystal structure to be influenced even more. Suitable nucleation bases include generally all materials which lead to a reduction of the nucleation energy required for the crystallization of the silicon relative to the nucleation energy in the region of the nucleation-inhibiting coating or the nucleation-inhibiting pot bottom material. The nucleation bases may in particular be applied to the nucleation-inhibiting coating. It may also be formed as an opening in the nucleation-inhibiting coating or the nucleation-inhibiting pot bottom material. Such nucleation bases may easily be formed in particular regions of the nucleation-inhibiting coating or in the pot bottom by mechanical or thermal processes or by means of a chemical reaction.

An embodiment of the invention is to apply, in a first step, the nucleation-inhibiting coating to the entire surface of one or more inner surfaces of the pot. Afterwards, individual regions of this coating are removed in a targeted manner by means of a laser beam. These are the regions where nucleation from the melt is supposed to start.

Another embodiment of the invention is to increase the surface energy of individual regions by means of a laser beam. This applies to both uncoated and coated inner pot surfaces. The increased surface energy results in increased wetting. These are the regions where nucleation from the melt is supposed to start.

Features and details of the invention will become apparent from the description of several embodiments by means of the drawing.

### BRIEF DESCRIPTION OF THE DRAWING

FIG. 1 shows a schematic cross-section through a vessel for receiving a silicon melt according to a first embodiment;

FIG. 2 shows a schematic cross-section through a vessel for receiving a silicon melt according to a second embodiment;

FIG. 3 shows a schematic cross-section through a vessel for receiving a silicon melt according to a third embodiment;

FIG. 4 shows a section, in the region of a bottom wall, from a schematic cross-section through a vessel for receiving a silicon melt according to a fourth embodiment; and

FIG. 5 shows a schematic cross-section through a vessel for receiving a silicon melt according to a fifth embodiment.

### DESCRIPTION OF THE PREFERRED EMBODIMENTS

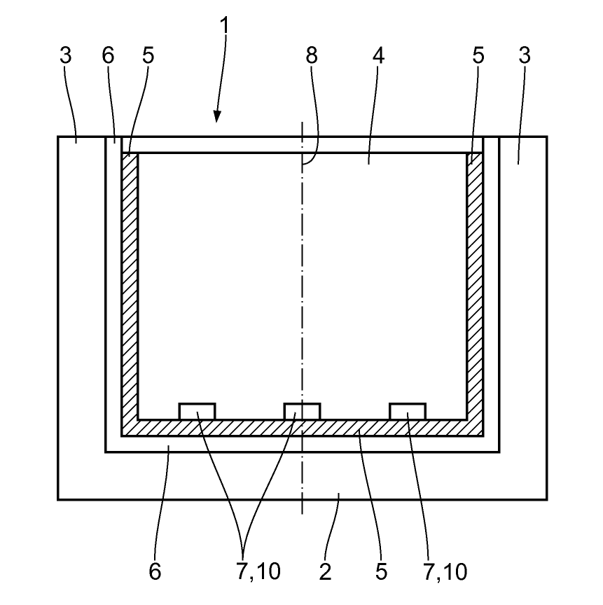

The following is a description, with reference to FIG. 1, of a first embodiment of the invention. According to the first embodiment, a device for the production of silicon blocks comprises a vessel 1 for receiving a silicon melt. The vessel 1 is a pot for melting silicon or a coquille for receiving a silicon melt. The vessel 1 is made of a material having a melting point above the melting point of silicon. It is in particular made of a ceramic material or of quartz. On its inside facing the interior space 4, the vessel 1 comprises a lining 6 of silicon nitride (Si₃N₄). The lining 6 need not necessarily consist of pure silicon nitride. It however advantageously consists of at least 75%, in particular at least 90%, in particular at least 95% of silicon nitride.

The vessel 1 comprises a bottom wall 2 and at least one side wall 3. The bottom wall 2 and the side walls 3 are together referred to as vessel walls. The vessel walls partially enclose an interior space 4 for receiving the silicon melt. On their inside facing the interior space 4, at least a portion thereof is provided with a nucleation-inhibiting surface in the form of a nucleation-inhibiting coating 5. The nucleation-inhibiting coating 5 covers at least 90%, preferably 100% of the inside of the side walls 3 and in particular of the bottom wall 2. In this respect, the lining 6 forms an all-over separation layer between the vessel walls 2, 3 and the nucleation-inhibiting coating 5.

The nucleation-inhibiting coating 5 consists of a material which inhibits heterogeneous nucleation at the boundary surface between coating 5 and silicon while causing a supercooling of the silicon melt. This means that the silicon melt may be cooled to temperatures below the melting point for silicon without causing crystals to form at the boundary surface between the coating 5 and the silicon melt. The coating 5 is in particular of a material which contains a compound with components of the group of the elements silicon (Si), nitrogen (N) and oxygen (O). At least 50%, in particular at least 75%, in particular at least 90% of the coating 5 consists of a compound of the group of silicon oxides or silicon oxynitrides, in particular of SiO₂ or Si₂N₂O. The term “silicon oxynitrides” includes all compounds in the form of SiₓN_{y}O_{z}, with x, y, z being unequal to zero.

Furthermore, at least one vessel wall 2, 3 comprises nucleation bases 7 in the form of applications 10 formed on the coating 5 for assisting crystal nucleation of the silicon melt. The nucleation bases 7 are preferably arranged on the bottom wall 2. The nucleation bases 7 are arranged in such a way as to come into contact with the silicon melt in the interior space 4 of the vessel 1.

The nucleation bases 7 may be materials which have a smaller contact angle relative to the silicon melt than the surrounding regions, in particular materials with a contact angle <90°. The nucleation bases 7 may in particular comprise a compound of silicon with one or several elements of the IV^{th} or V^{th} or VI^{th} group of the periodic table of the chemical elements, in particular carbon, nitrogen and oxygen. The nucleation bases 7 may also consist of graphite. According to the invention, it is however preferably required for the nucleation bases 7 to comprise at least one silicon compound, in particular silicon carbide (SiC), silicon nitride (Si₃N₄) or silicon oxynitride (Si₂N₂O), and to consist in particular of SiC or Si₃N₄. They may also consist of mono- or polycrystalline silicon. The nucleation bases 7 are rigidly connected to the vessel wall 2, 3. They form crystal nuclei where crystallization of the silicon melt is most likely to begin when the silicon melt cools down.

The nucleation bases 7 preferably consist of a material whose melting temperature is above that of silicon.

All nucleation bases 7 taken together cover a surface of no more than 25%, in particular no more than 10%, preferably no more than 3% of the inside of the bottom wall 2.

The following is a description of the method according to the invention for producing silicon blocks. In a first step, the vessel 1 for receiving the silicon melt is provided, with the inside of the vessel 1 being at least partially provided with the nucleation-inhibiting coating 5. Then the silicon melt is arranged in the vessel 1. To this end, the silicon melt may either be filled into the vessel 1 or solid silicon may be molten in the vessel 1. Afterwards, the silicon melt is cooled to cause crystallization thereof. The cooling process of the silicon melt is in particular spatially and temporally controlled. To this end, a temperature control device is provided which is not shown in the Figures.

When the silicon melt cools down slowly, for instance at a cooling rate in the range of 0.1° K/min to 10° K/min, a spontaneous nucleation in the region of the nucleation-inhibiting coating 5 is prevented over the entire surface thereof. At the same time, local nucleation in the regions of the nucleation bases 7 is facilitated. Therefore, the device according to the invention may be used to produce a silicon block having a defined, predetermined crystal structure in a simple manner.

The following is a description of a method for the production of the inventive device. In a first step, the vessel 1 for receiving the silicon melt is provided. The inside of this vessel 1 is provided with the silicon-nitride-containing lining 6. In order to apply the lining 6, a method from the group comprising spraying, dipping, impregnation and gas deposition methods is used.

The nucleation-inhibiting coating 5 is then applied to the lining 6. The coating 5 is applied at least to the bottom wall 2 of the vessel 1. It is preferably also applied to the side walls 3 of the vessel 1. The coating 5 covers at least 90%, in particular 100% of the inside of the vessel walls 2, 3, in particular the bottom wall 2.

In order to apply the coating 5, a method from the group comprising spraying, dipping, impregnation and gas deposition methods is used. In a preferred embodiment, the lining 6 is alternatively oxidised to form the nucleation-inhibiting coating 5. To this end, the vessel 1 with the silicon-nitride-containing lining 6 is heated for several hours, in particular at least three hours, preferably at least five hours in an oxygen-containing, in particular in an oxygen-enriched atmosphere, to a temperature of at least 500° C., in particular at least 750° C., preferably at least 1000° C. Due to the oxidation reaction taking place, at least one boundary layer of the side of the silicon-nitride-containing lining 6 facing the interior space of the vessel 1 is oxidised to form silicon oxynitride (Si₂N₂O).

After applying the nucleation-inhibiting coating 5, the nucleation bases 7 are applied to said coating 5. To this end, a pressure or coating method is used. If required, the inside of the vessel 1 may be provided with a mask for the application of the nucleation bases 7. It is conceivable as well to arrange the nucleation bases 7 manually on the inside of the vessel 1.

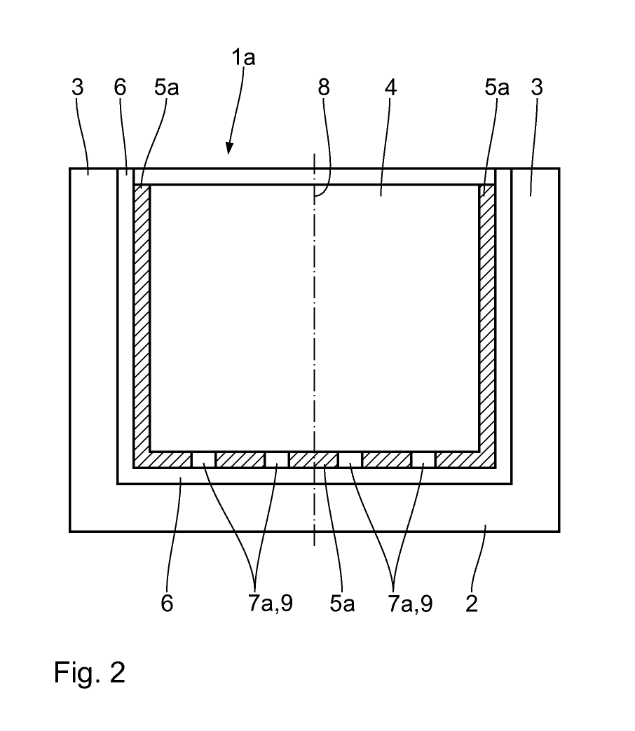

The following is a description, with reference to FIG. 2, of a second embodiment of the invention. Identical parts are denoted by the same reference numerals as in the first embodiment to the description of which reference is made. Differently constructed parts having the same function have the same reference numerals with an a added to them. According to the second embodiment, the nucleation bases 7a are designed as openings 9 in the nucleation-inhibiting coating 5. The openings 9 pass through the entire coating, thus allowing the lining 6 disposed underneath to come into contact with the silicon melt in the interior space 4 of the vessel 1a in the region of the openings 9. In the region of the openings 9, the silicon melt arranged in the interior space 4 of the vessel 1a is thus in particular in contact with the silicon nitride of the lining 6.

The openings 9 may be formed in the coating 5a mechanically, in particular by scratching, drilling or milling. In a particularly advantageous embodiment, it is alternatively intended to form the openings 9 in the coating 5a thermally, in particular by means of a laser method. A chemical method such as an etching method is conceivable for forming the openings 9 in the coating 5a.

In a variant of this embodiment, it is intended to arrange separate crystallization nuclei in the openings 9. Suitable materials for the crystallization nuclei include the same substances as used for the applications 10 in the first embodiment, in particular substances which comprise at least 50%, in particular at least 75%, preferably at least 90% of Si₃N₄, SiC or, in the case of a coating 5 with an SiO₂ content, comprise at least 50% of Si₂N₂O.

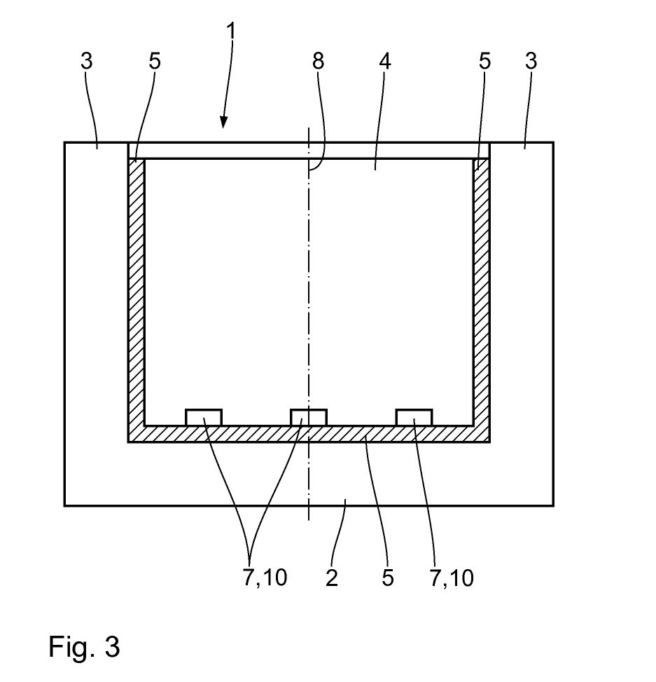

The following is a description, with reference to FIG. 3, of a third embodiment of the invention. According to the third embodiment, the nucleation-inhibiting coating 5 is applied directly to the inside of the vessel walls 2, 3. An application forming a separation layer is dispensed with in the third embodiment. According to this embodiment, the nucleation-inhibiting coating 5 is preferably of silicon oxynitride (Si₂N₂O). Coatings 5 as in the first embodiment are however conceivable as well.

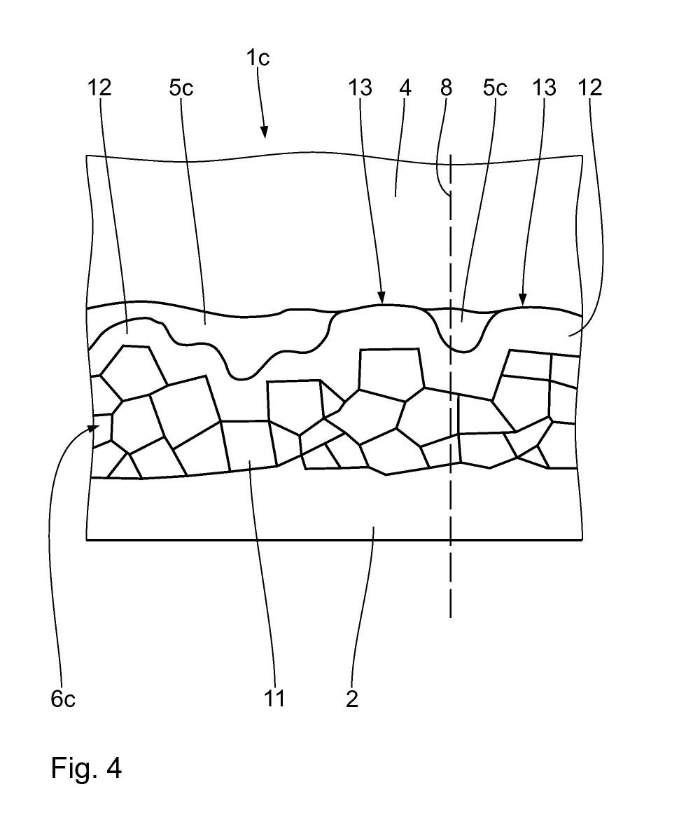

The following is a description, with reference to FIG. 4, of a fourth embodiment of the invention. Identical parts are denoted by the same reference numerals as in the first embodiment to the description of which reference is made. Differently constructed parts having the same function have the same reference numerals with a c added to them. According to this embodiment, the lining 6c consists of a plurality of crystallites 11. The crystallites 11 preferably contain at least 50%, in particular at least 75%, in particular at least 90% of silicon nitride. The crystallites are irregularly arranged on the inside of the vessel walls 2, 3, which results in a non-plane surface. This surface may also contain open pores or pore networks. The lining 6c is provided with the nucleation-inhibiting coating 5c. The coating 5c comprises a plurality of particles. The particles of the coating 5c preferably contain at least 50%, in particular at least 75%, in particular at least 90% of silicon dioxide. The particles of the coating 5c are much smaller than the crystallites 11 of the lining 6c. The particles of the coating 5c particularly have diameters in the order of magnitude of nanometers. At the outset, the coating 5 is preferably a nanoparticulate colloid. In other words, the coating 5c is able to enter the gaps between the crystallites 11 of the lining 6c. As a result, irregularities in the surface are partially smoothed out. Another result is that the coating 5c has a variable thickness in the direction of the central longitudinal axis 8.

In order to produce the vessel 1c, the vessel 1c is heated together with the lining 6c and the coating 5c. The heating process causes compaction of the coating 5c. Another result is that a reaction boundary layer 12 forms between the lining 6c and the coating 5c. The reaction boundary layer 12 preferably contains at least 50%, in particular at least 75%, in particular at least 90% of silicon oxynitride.

Depending on the thickness of the coating 5c, it is entirely converted into silicon oxynitride in local regions 13. The inside of the vessel 1c thus comprises laterally different SiO₂-rich and Si₂N₂O-rich regions.

When producing the silicon blocks, the coating 5c starts to dissolve after filling the silicon melt into the vessel 1c. The coating 5c with which the silicon melt comes into contact thus comprises regions having different compositions. It comprises in particular Si₂O-rich and Si₂N₂O-rich regions. Depending on the thickness of the coating 5c, it can be achieved that the silicon melt comes into contact with Si₃N₄-rich regions. While the regions with the highest oxygen content act as nucleation inhibitors, the regions with the lowest oxygen content form nucleation bases.

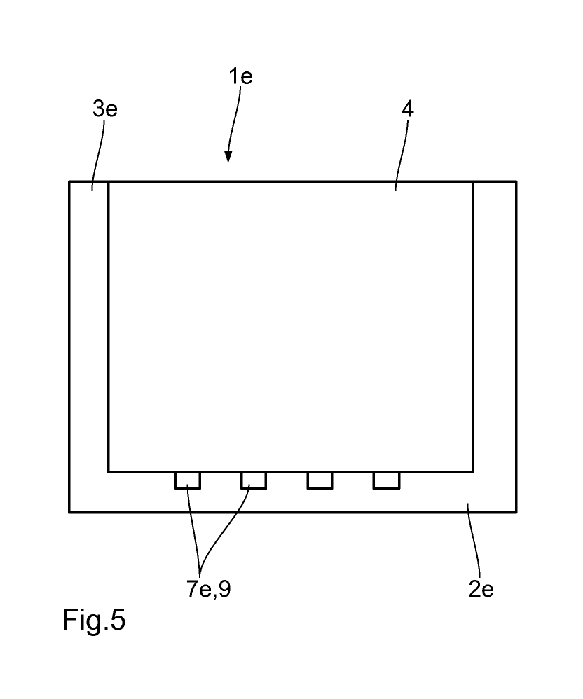

The following is a description, with reference to FIG. 5, of a fifth embodiment of the invention. Identical parts are denoted by the same reference numerals as in the first embodiment to the description of which reference is made. Differently constructed parts with the same function have the same reference numerals with an e added to them.

The bottom wall 2e of the vessel 1e, in particular the vessel 1e, consists of a nucleation-inhibiting material such as silicon oxynitride ceramics or boron nitride ceramics. The bottom wall 2e is provided with local openings 9 which fully or partially pass through the bottom wall 2e. These openings 9 are provided with nucleation bases 7 according to the above embodiments. This method allows both the separation layer 6 and the nucleation-inhibiting coating 5 to be dispensed with.

The openings 9 may easily be formed in the bottom wall 2e by mechanical means. The nucleation bases are also provided in the openings 9 by mechanical means.

A combination of the described embodiments is of course possible. For example, both applications 10 and openings 9 may be provided in the form of nucleation bases. It is conceivable as well, also in the example of the fourth embodiment, to provide a predetermined pattern of nucleation bases 7, in particular in the form of openings 9 in the coating 5c or in the form of applications 10 on the coating 5c

What is claimed is:

1. A device for the production of silicon blocks comprising
a. a vessel (1; 1a; 1c; 1e) for receiving a silicon melt;
b. with at least one vessel wall (2, 3) comprising a nucleation-inhibiting surface on at least part of an inner side; and
c. with the at least one vessel wall (2, 3) comprising at least one nucleation basis (7; 7a) on its inner side which is provided with the nucleation-inhibiting surface for assisting the formation of crystallization nuclei of the silicon melt.

2. A device according to claim 1, with the at least one vessel wall (2, 3) comprising several nucleation bases (7; 7a) on its inner side.

3. A device according to claim 1, with the nucleation-inhibiting surface being formed by a nucleation-inhibiting vessel material (2e).

4. A device according to claim 1, with the nucleation-inhibiting surface being formed by a nucleation-inhibiting coating (5, 5a, 5c).

5. A device according to claim 1, wherein the at least one vessel wall (2, 3) is at least one of a bottom wall (2) and a side wall (3).

6. A device according to claim 1, wherein the nucleation-inhibiting surface covers at least 90% of the inside of the at least one vessel wall (2, 3).

7. A device according to claim 1, wherein the nucleation-inhibiting surface covers 100% of the inside of the at least one vessel wall (2, 3).

8. A device according to claim 4, wherein the coating (5; 5a; 5c) is of a material which comprises silicon and proportions of oxygen.

9. A device according to claim 8, wherein the coating (5; 5a; 5c) comprises a compound of one of the group of silicon oxides and silicon oxynitrides, which compound makes up at least 50% of the mass of the coating.

10. A device according to claim 8, wherein the compound of the coating (5; 5a; 5c) is one of the group of SiO₂ and Si₂N₂O.

11. A device according to claim 8 wherein the compound of the coating (5; 5a; 5c) makes up at least 90% of its mass.

12. A device according to claim 1, wherein the at least one nucleation basis (7; 7a; 7e) has a smaller contact angle relative to the silicon melt than the material of the nucleation-inhibiting surface.

13. A device according to claim 1, wherein the at least one nucleation basis (7; 7a) comprises one of the group comprising graphite (7e) and a compound of the group of one of the group of silicon carbides and silicon nitrides.

14. A device according to claim 13, wherein the at least one nucleation basis (7; 7a) comprises one of the group of SiC and Si₃N₄

15. A device according to claim 1, wherein the entirety of all nucleation bases (7; 7a) covers a surface portion of no more than 25% of the inside of the at least one vessel wall (2, 3).

16. A device according to claim 15, wherein the entirety of all nucleation bases (7; 7a) covers a surface portion of no more than 10% of the inside of the at least one vessel wall (2, 3)

17. A device according to claim 15, wherein the entirety of all nucleation bases (7; 7a) covers a surface portion of no more than 3% of the inside of the at least one vessel wall (2, 3)

18. A method for the production of a device according to the invention comprising the following method steps:
providing a vessel (1; 1a; 1c, 1e) for receiving a silicon melt, the vessel (1; 1a; 1c, 1e) being provided with a nucleation-inhibiting surface on at least one inner side;
forming at least one nucleation basis (7; 7a) on the inner side which is provided with the nucleation-inhibiting surface (5; 5a; 5c).

19. A method according to claim 18, with the nucleation-inhibiting surface being formed by a nucleation-inhibiting vessel material.

20. A method according to claim 18, with the nucleation-inhibiting surface being formed by a nucleation-inhibiting coating (5; 5a; 5c).

21. A method according to claim 20, wherein the nucleation-inhibiting coating (5; 5a; 5c) is applied to the inside of the vessel (1; 1a; 1c) in the form of a nanoparticulate colloid.

22. A method according to claim 20, wherein the vessel (1; 1a; 1c) with the nucleation-inhibiting coating (5; 5a; 5c) is heated to form a reaction boundary layer (12) between the coating (5; 5a; 5c) and a layer (6; 6c) disposed underneath.

23. A method according to claim 18, wherein the at least one nucleation basis (7; 7a) is formed by at least one of the group of mechanical, thermal and chemical methods.

24. A method according to claim 20, wherein the at least one nucleation basis (7; 7a; 7e) is formed by local removal of the nucleation-inhibiting coating (5; 5a, 5e) by means of a laser beam.

25. A method according to claim 23, wherein the at least one nucleation basis (7; 7a; 7e) is formed by locally increasing the surface energy by means of a laser beam.

26. A method for the production of silicon blocks comprising the following method steps:
providing a vessel (1; 1a; 1c; 1e) for receiving a silicon melt, which vessel (1; 1a; 1c; 1e) comprises, on at least part of the inside of at least one vessel wall (2, 3), a nucleation-inhibiting surface and at least one nucleation basis (7; 7a) on the inside which is provide with the nucleation-inhibiting surface (5; 5a; 5c);
arranging a silicon melt in the vessel (1; 1a; 1c; 1e) by one of the methods comprising pouring in liquid silicon and melting solid silicon;
cooling the at least one vessel wall (2, 3) with the nucleation-inhibiting surface for crystallization of the silicon melt.
